(19) United States
(12) Patent Application Publication
(10) Pub. No.: US 2006/0023423 A1
(43) Pub. Date: Feb. 2, 2006

(54) Expandable heat sink

(75) Inventors: Kevin Kuo, Shindian City (TW); James Hsyu, Shindian City (TW); Langhans Chang, Shindian City (TW); Robert Kuo, Shindian City (TW)

Correspondence Address: BACON & THOMAS, PLLC, 625 SLATERS LANE, FOURTH FLOOR, ALEXANDRIA, VA, 22314, US

(73) Assignee: VIA Technologies, Inc., Shindian City (TW)

(21) Appl. No.: 10/988,593

(22) Filed: Nov. 16, 2004

(30) Foreign Application Priority Data
Jul. 30, 2004 (TW) 093123038

(51) Int. Cl. H05K 7/20

(52) U.S. Cl. 361/697

(57) ABSTRACT

An expandable heat sink is used for dissipating heat of a heat source on a main board. The heat sink comprises a main body and an expanded body. The main body comprises a main-body contact surface, which is contacted with the heat source, and a plurality of first fins. The first fins compose a main connecting portion. Furthermore, the expanded body comprises a plurality of second fins and the second fins compose an expanded connecting portion. The expanded connecting portion is removably connected to the main connecting portion.

### BACKGROUND OF THE INVENTION

1. Field of Invention

The invention relates to a heat sink and, in particular, to an expandable heat sink.

2. Related Art

Micro processors and chips grow with stronger functions based on the advanced semiconductor technology. However, powerful chips accompany with many problems. The heat-dissipating issue, for example, is the most serious among the problems. Because the heat-dissipating issue of the CPU is more serious than that of other devices in the prior art, regarding to a computer, a heat sink is installed on the CPU to avoid malfunctions resulted from the heat-dissipating problem. Recently, various kinds of chips, such as system chip and GPU (graphic processing unit), are powerful as well as the CPU. Therefore, not only the heat problem produced by CPU should be concerned, but also the heat-dissipating problems produced by other devices in the computer should be concerned.

Referring to FIG. 1, a heat-dissipation method for a CPU 12 is described. In a common case, a heat sink 11 is provided for dissipating the redundant heat produced by the CPU 12. The CPU 12 is installed on a socket 13, and the heat sink 11 is fixed over the socket 13 by a mounting component 111. As a result, the heat sink 11 contacts tightly with the CPU 12. Furthermore, a heat conduction material may be applied between the heat sink 11 and a contact surface 112 of the CPU 12.

The heat sink having larger surface can provide better heat dissipating efficiency because the heat exchanging efficiency of the heat sink is proportion to its superficies. However, the conventional heat sink is not expandable. In other words, to increase the superficies of the heat sink by adding an additional heat sink is not allowed. Therefore, the inexpansible heat sink must be substituted to obtain larger heat sink superficies for enhancing the heat dissipating efficiency. As a result, the conventional inexpansible heat sink is worse flexible in installation.

It is therefore a subjective of the invention to provide a heat sink, which is expandable for flexibly expanding the superficies thereof.

### SUMMARY OF THE INVENTION

In view of the foregoing, the invention is to provide an expandable heat sink, which is expandable and flexibly increases the superficies thereof.

To achieve the above, the invention provides an expandable heat sink, which is used for dissipating heat of a heat source on a main board, and comprises a main body and an expanded body. The main body comprises a plurality of first fins, and a main-body contact surface, which is contacted with the heat source. At least two of the first fins compose a main connecting portion. In addition, the expanded body comprises a plurality of second fins and at least two of the second fins compose an expanded connecting portion. The expanded connecting portion is removably connected to the main connecting portion.

As mentioned above, since the heat sink comprises a main connecting portion for connecting with an expanded body, the heat sink according to the invention is expandable. Therefore, an expanded body is selectively added into or removed from the heat sink so as to adapt the suitable combination of the main body and the expanded body to the heat dissipating environment, such as the space that various kinds of the main board are installed in. As a result, the combination enhances the heat dissipating efficiency.

### BRIEF DESCRIPTION OF THE DRAWINGS

The invention will become more fully understood from the detailed description given hereinbelow illustration only, and thus is not limitative of the present invention, and wherein:

FIG. 1 is a schematic diagram showing the conventional heat sink;

FIG. 2A is a schematic diagram showing an expandable heat sink according to a preferred embodiment of the invention;

FIG. 2B is a schematic diagram showing an additional expandable heat sink according to the preferred embodiment of the invention, wherein a main-body connecting portion comprises a groove;

FIG. 3A is a schematic diagram showing an expandable heat sink according to a preferred embodiment of the invention installed on a main board, wherein a main body is contacted with a first heat source;

FIG. 3B is a schematic diagram showing an expandable heat sink according to a preferred embodiment of the invention installed on a main board, wherein a main body is contacted with a first heat source and an expanded body is contacted with a second heat source;

FIG. 3C is a schematic diagram showing an expandable heat sink according to a preferred embodiment of the invention installed on a main board, wherein a main body is contacted with a first heat source, an expanded body is contacted with a second heat source and another expanded body is without contacting with heat source; and

FIG. 4 is a schematic diagram showing an expandable heat sink according to a preferred embodiment of the invention installed inside a host.

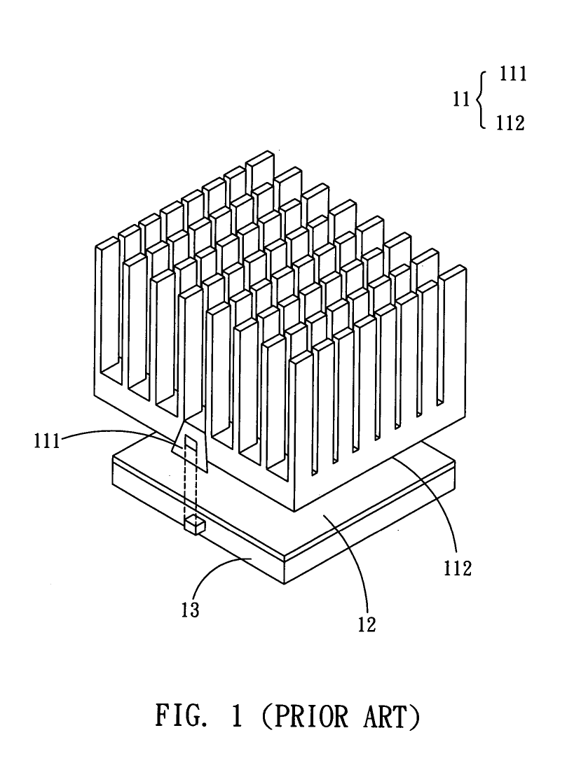

### DETAILED DESCRIPTION OF THE INVENTION

The present invention will be apparent from the following detailed description, which proceeds with reference to the accompanying drawings, wherein the same references relate to the same elements.

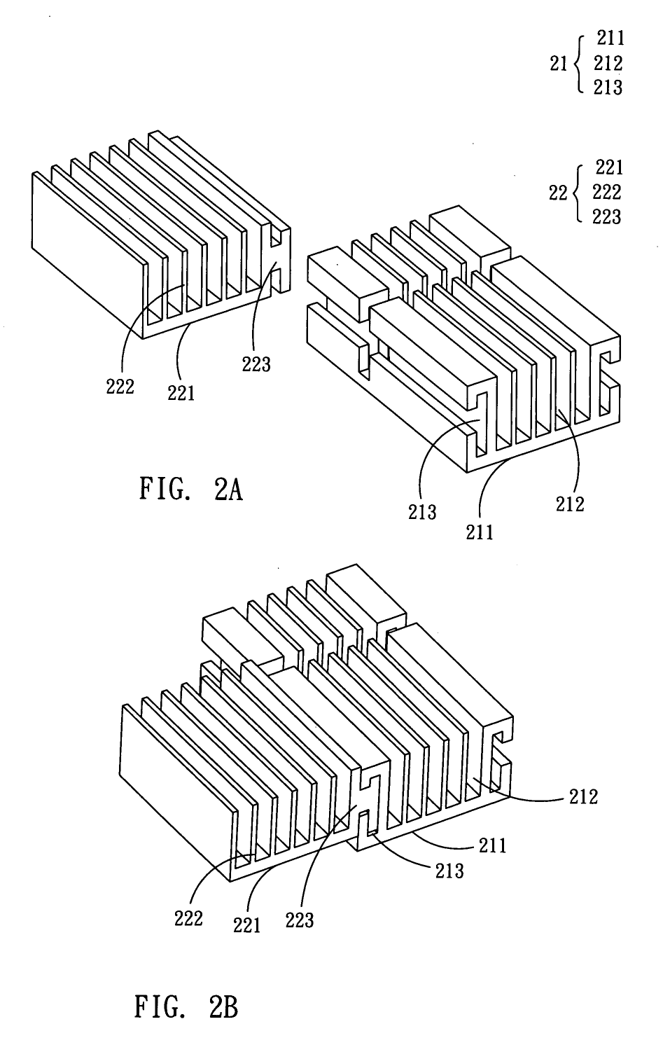

Referring to FIG. 2A, an expandable heat sink according to a preferred embodiment of the invention comprises a main body 21 and an expanded body 22. In the embodiment, the main body 21 comprises a main-body contact surface 211, which is contacted with a heat source, and a plurality of first fins 212. At least two of the first fins 212 compose a main connecting portion 213 for connecting to the expanded body 22. In addition, the expanded body 22 comprises an expanded-body contact surface 221 and a plurality of second fins 222. At least two of the second fins 222 compose an expanded connecting portion 223 for connecting with the main body 21. In practice, the expanded connecting portion 223 is removably connected to the main connecting portion 213.

Referring to FIG. 2B, in the embodiment, the main connecting portion 213 provides a groove, and the expanded connecting portion 223 is slid into the groove. Accordingly, the main body 21 connects with the expanded body 22. In addition, the expanded connecting portion 223 may provide an additional groove, so that the main connecting portion 213 can be slid into the additional groove. In such a case, the main body 21 can also connect with the expanded body 22. Besides, the main connecting portion 213 can be not only connected the expanded connecting portion 223 with the groove, but also screwed on or wedged with the expanded connecting portion 223.

The main body 21 and the expanded body 22 are made of metal such as aluminum or copper. Due to the displacement(s) between the contact surfaces of the main body 21 and the expanded body, a first heat conduction material is applied to the surfaces between the main connecting portion 213 and expanded connecting portion 223. The first heat conduction material is provided to increase the heat dissipating efficiency between the main body 21 and the expanded body 22.

An example is described below in order to illustrate the expandable heat sink according to the preferred embodiment of the invention.

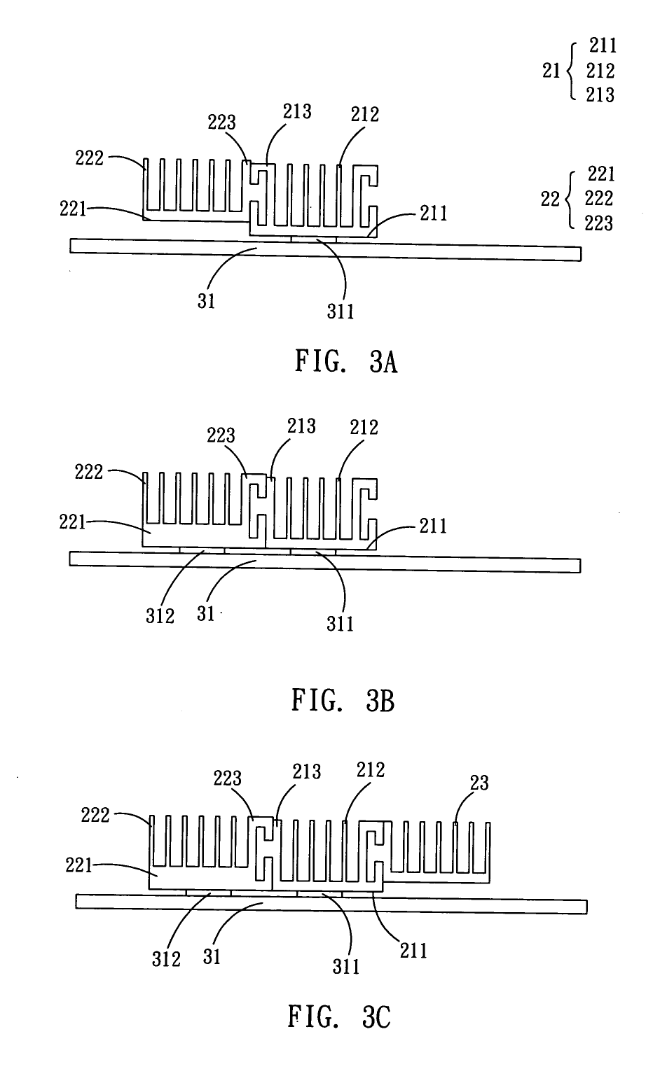

Referring to FIG. 3A, an expandable heat sink according to a preferred embodiment of the invention comprises a main body 21 and an expanded body 22. The main body 21 is screwed on a main board 31 and is installed on a first heat source 311 of the main board 31. A second heat conduction material is applied to the main-body contact surface 211 for increasing the heat dissipating efficiency between the main body 21 and the first heat source 311. The first heat source 311 can be an IC. In addition, the main connecting portion 213 provides a groove and the expanded connecting portion 223 is slid into the groove so as to connect the main body 21 and the expanded body 22. Certainly, a first heat conduction material can be applied to the surfaces between the main connecting portion 213 and expanded connecting portion 223 for increasing the heat dissipating efficiency between the main body 21 and the expanded body 22.

Referring to FIG. 3B, an expandable heat sink according to a preferred embodiment of the invention comprises a main body 21 and an expanded body 22. Differing from the expandable heat sink shown in FIG. 3A, the expanded connecting portion 223 shown in FIG. 3B provides a groove, and the main connecting portion 213 is slid into the groove. Accordingly, the main body 21 connects with the expanded body 22. In addition, the expanded body 22 can be screwed on a main board 31 and is installed on a second heat source 312 of the main board 31. In this case, a third heat conduction material is applied to the expanded-body contact surface 221. The third heat conduction material is provided to increase the heat dissipating efficiency between the expanded body 22 and the second heat source 312. The second heat source 312 can be an IC.

Referring to FIG. 3C, an expandable heat sink according to a preferred embodiment of the invention comprises a main body 21, an expanded body 22 and an expanded body 23. Differing from those shown in FIG. 3B, the main body 21 shown in FIG. 3C connects with two expanded bodies, including the expanded body 22 and the expanded body 23. The expanded body 23 can be a flexible removable element for providing expansibility of other devices in the host. This configuration is benefit to avoid replacing the heat sink purposely resulting from the changed space in the host. The configuration also has the ability to replace different-size heat sink adapting to the restricted space in the host.

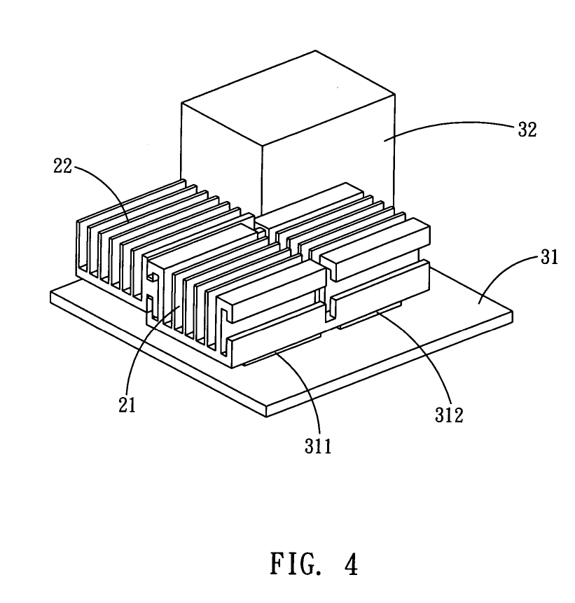

Referring to FIG. 4, an expandable heat sink according to a preferred embodiment of the invention is installed inside a host. Avoiding from being interfered with a power supply 32, a proper combination of the main body 21 and the expanded body 22 is designed in the “L” shape. In this embodiment, the main body 21 contacts with the first heat source 311 and a second heat source 312 on the main board 31 for dissipating heat. Therefore, the expandable heat sink is able to adapt to the environment inside the host. As a result, a suitable combination of the main body 21 and the expanded body 22 is provided, so that a system with better heat dissipating efficiency is obtained.

As mentioned above, the heat sink according to the preferred embodiment of the invention is expandable because the heat sink comprises a main connecting portion for connecting with an expanded body. Therefore, an expanded body is selectively added into or removed from the heat sink in order to adapt the suitable combination of the main body and the expanded body to the heat dissipating environment, such as the space that various kinds of the main boards are installed inside, and to increase the heat dissipating efficiency.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An expandable heat sink, which is used for dissipating heat of a heat source on a main board, comprising:
a main body, which comprises a main-body contact surface and a plurality of first fins, wherein the main-body contact surface is contacted with the heat source and at least two of the first fins compose a main connecting portion; and
an expanded body, which comprises a plurality of second fins, wherein at least two of the second fins compose an expanded connecting portion and the expanded connecting portion is removably connected to the main connecting portion.

2. The expandable heat sink as recited in claim 1, wherein the main body and the expanded body are made of metal.

3. The expandable heat sink as recited in claim 1, wherein the main body and the expanded body are made of aluminum.

4. The expandable heat sink as recited in claim 1, wherein the main body and the expanded body are made of copper.

5. The expandable heat sink as recited in claim 1, wherein the main connecting portion provides a groove that the expanded connection portion is slid into.

6. The expandable heat sink as recited in claim 1, wherein the expanded connecting portion provides a groove and the main connecting portion is slid into the groove.

7. The expandable heat sink as recited in claim 1, wherein the expanded body is screwed on the main body.

8. The expandable heat sink as recited in claim 1, wherein the main body is wedged with the expanded body.

9. The expandable heat sink as recited in claim 1, further comprising:
a first heat conduction material, which is applied between the main body and the expanded body.

10. The expandable heat sink as recited in claim 1, further comprising:
a second heat conduction material, which is applied to the main-body contact surface and is located between the main-body contact surface and the heat source.

11. The expandable heat sink as recited in claim 1, wherein the expanded body comprises:
an expanded-body contact surface, which is contacted with the heat source.

12. The expandable heat sink as recited in claim 11, further comprising:
a third heat conduction material, which is applied to the expanded-body contact surface and is located between the expanded-body contact surface and the heat source.

13. The expandable heat sink as recited in claim 1, wherein the heat source is at least one integrated circuit.

14. The expandable heat sink as recited in claim 1, wherein the expandable heat sink is fixed on the main board.
